(19) United States
(12) Patent Application Publication
(10) Pub. No.: US 2004/0150961 A1
(43) Pub. Date: Aug. 5, 2004

(54) System and method for configuring a circuit

(76) Inventor: Jeffrey Michael Frechette, Boise, ID (US)

Correspondence Address: HEWLETT-PACKARD COMPANY, Intellectual Property Administration, P.O. Box 272400, Fort Coliins, CO, 80527-2400, US

(21) Appl. No.: 10/355,807

(22) Filed: Jan. 30, 2003

(51) Int. Cl. H05K 1/14

(52) U.S. Cl. 361/736

(57) ABSTRACT

A multi-state indicator includes a section connecting a first trace to a second trace adapted to facilitate application of force to said section to disconnect said section from said first and/or second trace(s) and to disconnect said first trace from said second trace. In addition, the multi-state indicator includes circuitry to indicate a state based on whether said first trace connects to said second trace.

### BACKGROUND

Circuit configuration systems may be employed in various demanding applications including engine ignition systems, finite state machines for controlling streetlights and vending machines, and formatter Printer Circuit Assemblies (PCA's) for controlling printer modes. Such systems are used to reliably reconfigure associated systems to achieve a desired operational mode, state, or configuration.

Circuit configuration systems may be used in printer applications, where printer software or circuits are often adjusted or replaced in accordance with desired printer capabilities. A printer manufacturer may wish to sell printers with different capabilities to different target markets at different prices. For example, a manufacturer may wish to sell printers with and without duplex functionality to target different markets.

In one way in which it is possible to change printer functionality, a printer's existing formatter PCA may be replaced with a different formatter PCA that enables or defines a different feature set. However, a given printer line may use several different types of formatter PCA's. Accurate forecasts of formatter PCA sales quantities are used to avoid building, testing, storing, shipping, and receiving too many or too few formatter PCA's. However, accurately forecasting demand for plural types of formatter PCA's may be problematic. Furthermore, different formatter PCA's may be supplied by different vendors, which further increases shipping costs and inefficiencies. Consequently, formatter PCA replacement for different printer configurations may be costly and inefficient.

### SUMMARY OF THE INVENTION

A multi-state indicator includes a section connecting a first trace to a second trace adapted to facilitate application of force to said section to disconnect said section from said first and/or second trace(s) and to disconnect said first trace from said second trace. In addition, the multi-state indicator includes circuitry to indicate a state based on whether said first trace connects to said second trace.

### BRIEF DESCRIPTION OF THE DRAWINGS

FIG. 1 is a block diagram of a printer incorporating a circuit configuration system constructed in accordance with the teachings of this disclosure.

FIG. 2 is a diagram of a first alternative embodiment of the printer of FIG. 1.

FIG. 3 is a diagram of a second alternative embodiment of the circuit configuration system of FIG. 1.

FIG. 4 is a diagram of a third alternative embodiment of the circuit configuration system of FIG. 1.

FIG. 5 is a diagram of a fourth alternative embodiment of the circuit configuration system of FIG. 1.

### DETAILED DESCRIPTION OF THE DRAWINGS

While embodiments of the circuit configuration system are illustrated with reference to particular applications, it should be understood that other embodiments of the circuit configuration system are possible. Those having ordinary skill in the art and access to the teachings provided herein will recognize additional modifications, applications, and embodiments of the circuit configuration system and additional fields in which these embodiments would be of significant utility.

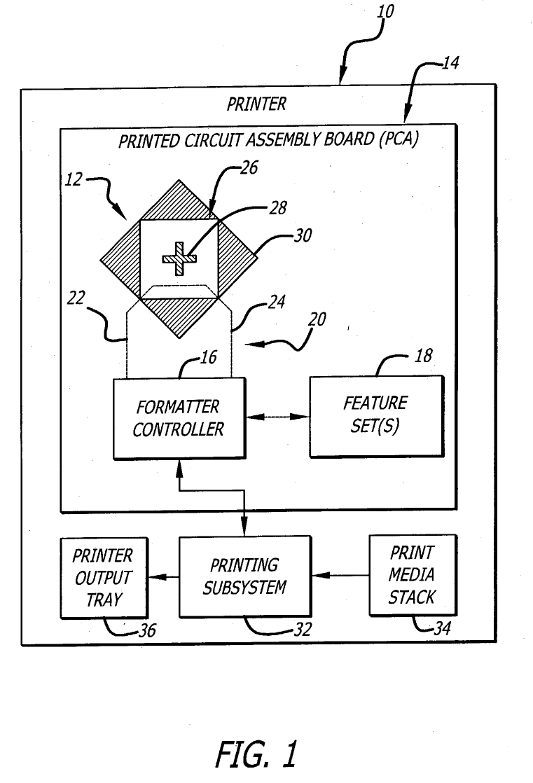

FIG. 1 is a block diagram of a printer 10 incorporating a circuit configuration system 12 constructed in accordance with the teachings of this disclosure. For clarity, various components, such as power supplies, laser-steering mirrors, chargers, various rollers, fuser heat lamps, fuser oil applicators, and so on, have been omitted from the figures. However, those skilled in the art with access to the present teachings will know which components to implement and how to implement them to meet the needs of a given application.

The printer 10 includes a Printed Circuit Assembly board (PCA) 14, also called a formatter PCA, that includes the circuit configuration system 12 and accommodates a controller 16, which has access to a feature set 18. The controller 16 is connected to the circuit configuration system 12 via an inner-layer trace 20 that includes a first trace section 22 and a second trace section 24. The inner-layer trace is routed through the circuit configuration system 12.

The circuit configuration system 12 includes a breakout tab 26 that includes an etched slot 28 disposed approximately in the center of the breakout tab 26. In the present specific embodiment, the etched slot 28 is shaped to accommodate a Phillips-head screwdriver. Those skilled in the art will appreciate that the etched slot 28 may be another shape, such as a rectangular slot, and that the slot 28 may be positioned off-center on the breakout tab 26, without departing from the scope of the present invention. The slot 28 may also be designed to accommodate a tool other than a screwdriver.

The breakout tab 26 is partially surrounded by a diamond-shaped outer etched pattern 30. The four corners of the breakout tab 26 contact or are integrated with the surrounding PCA 14 at the four sides of the diamond-shaped outer etched pattern 30. The inner-layer trace 20 is routed between surface layers of the PCA 14, through, one or more corners of the breakout tab 26, and back to the controller 16.

The controller 16 selectively accesses the feature set 18 on the PCA 14 and communicates with a printing subsystem 32 positioned off the PCA 14. The printing subsystem 32 receives input print media, such as paper, from a print media stack 34 and provides printed output to a printer output tray 36. The printing subsystem 32 includes various components required to implement printing functions. For example, the printing subsystem 32 may be implemented as an electro-photographic printing subsystem that includes a printer controller, a laser, an electrophotographic drum, a toner reservoir, a transfer belt, a fuser, and so on, (not shown) which are known in the art and are used in many LaserJet printing applications. The formatter controller 16 may incorporate the main printer controller and may be implemented in firmware or software. Alternatively, the formatter controller 16 may be separate from the main printer controller.

In operation, certain available features of the printer 10, which are defined via the feature set 18, are selectively enabled or disabled via the circuit configuration system 12. In the present specific embodiment, the printer 10 accommodates two feature sets 18. For example, one feature set may have duplexing (double-sided printing) enabled, while the second feature set may not include duplexing. To select one feature set, a screw driver is inserted into the etched slot 28 in the breakout tab 26 and twisted to break the inner-layer trace 20, thereby permanently separating the first trace section 22 from the second trace section 24. The breakout tab 26 may be removed from the printer 10 and discarded. Alternatively, the breakout tab 26 may remain connected to the PCA 14 via an axle or other mechanism (not shown).

To select another feature set having additional features, the breakout tab 26 is left in place. Those skilled in the art with access to the present teachings will know how to implement the feature set 18 to meet the needs of a given application without undue experimentation.

The controller 16 monitors the inner-layer electrical trace 20 and determines whether the trace is open, i.e., broken or is intact, i.e., closed. The controller 16 then enables certain features in response thereto by picking a feature set, which contains those certain features or functionality, from the feature sets 18 in accordance with predetermined methodology.

Hence, the breakout tab 26 may be used to selectively change the functional configuration of the printer 10 by facilitating breaking of the trace 20. The breakout tab 26 may also be thought of as a mechanism for changing the configuration of the printer 10 by facilitating removal of a portion of the inner-layer trace 20.

Use of the breakout tab 12 also facilitates determination of the configuration of the printer 10. To determine if a certain feature set is enabled, a user or manufacturer may simply inspect the PCA 14 to determine if the breakout tab 26 is present. This may require physically removing a printer cover (not shown) or other components to expose the PCA 14. Alternatively, a window or other opening (not shown) in the printer 10 may be included to facilitate viewing the breakout tab 26. In addition, an internal mirror, magnifying glass, or other scope device (not shown) may be strategically positioned in the printer 10 to facilitate viewing the breakout tab 26.

In the preferred embodiment, the feature set that is selected by the controller 16 from the feature sets 18 when the inner-layer trace 20 is broken has fewer features than the feature set selected when the inner-layer trace 20 is intact. This prevents end users from enhancing printer features by breaking the breakout tab 26 with a screwdriver.

Enabling selective breaking of the inner-layer trace 20 or removal of a portion of the inner-layer trace 20 via the circuit configuration system 12 allows a manufacturer to permanently define available product features at final product integration. User tampering with the circuit configuration system 12 to obtain more product features is inhibited due to the complexity involved in reconnecting broken traces. User tampering is further inhibited by the fact that the trace 20 is inner-layer, i.e., is beneath the surface of the PCA 14 and cannot readily be seen by looking at the PCA 14.

The circuit configuration system 12 acts as a two-state indicator. A state or operational mode is mechanically and permanently selectable from among two possible states by a manufacturer at final product integration. Several two-state indicators 12 may be implemented on the PCA to define more states and associated feature sets. The number of states that can be defined is 2′, where n is the number of two-state indicators 12 implemented on the PCA. For example, four two-state indicators 12 enable a manufacturer to define sixteen different feature sets. In general, states associated with feature sets having more functions are associated with fewer broken traces.

The controller 16 determines currently available printer features with reference to the two-state circuit configuration system 12, which defines the current state or configuration of the printer 10. The controller 16 then adjusts control signaling to the printing subsystem 32 so that only allowed features are implemented via the printing subsystem 32.

With access to the present teachings, those skilled in the art will be able to implement the various components of the printer 10 without undue experimentation. For example, the circuit configuration system 12 may be implemented via standard circuit board etching techniques.

The circuit configuration system 12 may also be implemented via Microelectromechanical Systems (MEMS) or nanosystem technologies. In these applications, the small size of the circuit configuration system 12 may necessitate use of special techniques, machines, and or instruments to break the inner-layer trace 20 via the breakout tab 26.

In the present specific embodiment, torque is applied to the breakout-tab 26 to break the inner-layer trace 20. However, other forces may be applied to the breakout tab 26 to break the trace 20, and a screwdriver slot or opening may not be required. For example, a sticky-tab or peel-away tape (not shown) may be attached to the breakout tab 26 so that when the tab is pulled, the corners of the breakout tab 26 separate from the PCA 14, thereby breaking the trace 20. Alternatively, circuit board cavities (not shown) may be positioned beneath the corners of the breakout tab 26 so that a pushing force from a screw driver at the corners of the breakout tab 26 will fold the corners into the circuit board cavities, thereby breaking the trace 20.

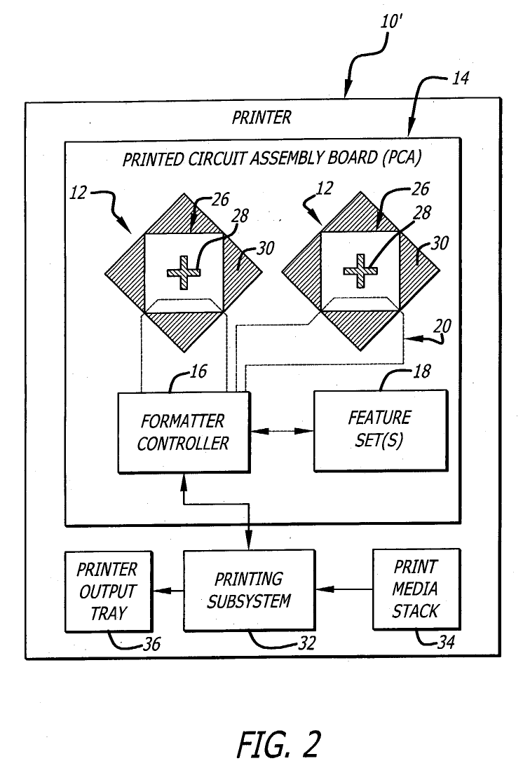

FIG. 2 is a diagram of a first alternative embodiment 10′ of the printer 10 of FIG. 1. The operation of the printer 10′ of FIG. 2 is similar to the operation of the printer 10 of FIG. 1 with the exception that the printer 10′ includes two circuit configuration systems 12 that enable a manufacturer to select one of four possible operational modes and corresponding feature sets. The feature sets may be defined by selectively breaking one or both of the traces 20 or leaving the traces 20 intact.

The circuit configuration systems 12, which are implemented as breakout tabs, may be associated with different features of the feature set 18. Each breakout tab 12 could be associated with one or more corresponding features of the feature set 18. Consequently, individual features of the feature set 18 may be turned off by actuating specific configuration systems 12.

Alternatively, different functions or features are associated with different configurations of breakout tabs. For example, in a system (not shown) with five breakout tabs, if two out five breakout tabs are broken, a certain feature set may be enabled. If three out of five breakout tabs are broken, a different feature set associated with different functions may be enabled.

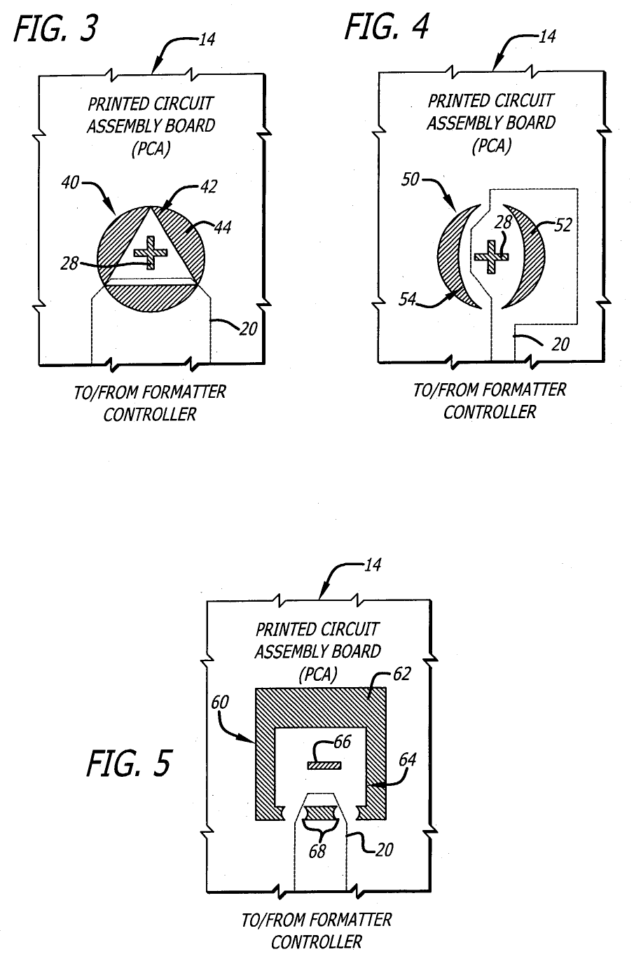

FIG. 3 is a diagram of a second alternative embodiment 40 of the circuit configuration system 12 of FIG. 1. The triangular circuit configuration system 40 includes a triangular breakout tab 42 that accommodates the etched slot 28 and is partially surrounded by a circular etched pattern 44. The triangular breakout tab 42 is connected to or integrated with the surrounding PCA 14 only at the corners of the triangular breakout tab 42, which contact or are integrated with the edges of the circular etched pattern 44. The trace 20 is routed through two corners of the triangular breakout tab 42. The operation of the triangular circuit configuration system 40 of FIG. 3 is similar to operation of the square circuit configuration system 12 of FIG. 1.

FIG. 4 is a diagram of a third alternative embodiment 50 of the circuit configuration system 12 of FIG. 1. The oval circuit configuration system 50 includes an alternative circular etched pattern 52 that partially surrounds an oval breakout tab 54. The oval breakout tab 54 accommodates the etched slot 28. The oval breakout tab 54 is connected to or integrated with the surrounding PCA 14 at edges of the circular etched pattern 52 only at opposite ends of the oval breakout tab 54. The trace 20 is routed through the opposite ends of the oval breakout tab 54. The operation of the oval circuit configuration system 50 is similar to the operation of the square circuit configuration system 12 of FIG. 1.

FIG. 5 is a diagram of a fourth alternative embodiment 60 of the circuit configuration system 12 of FIG. 1. The rectangular circuit configuration system 60 includes a square-shaped etched pattern 62 that surrounds a rectangular-shaped breakout tab 64, which accommodates an etched rectangular slot 66 for accommodating a flat-head screwdriver. The rectangular breakout tab 64 is connected to the surrounding PCA 14 via legs 68 that extend from the rectangular breakout tab 64 to an edge of the surrounding square-shaped etched pattern 62. The trace 20 is routed through the rectangular breakout tab 64 via the legs 68. In operation, when a flat-head screwdriver is inserted in the etched rectangular slot 66 and twisted, one or both of the legs 68 separate, thereby breaking the electrical trace 20.

Alternatively, two different traces (not shown) may be routed onto the breakout tab 66. One trace may be routed to and from the rectangular breakout tab 64 via the same leg. A second trace may be routed to and from rectangular breakout tab 64 via the remaining leg. Consequently, a manufacturer may break one or both legs depending on how the screwdriver is twisted in the rectangular etched slot 66, thereby breaking either the first trace and/or the second trace routed through the first leg and/or the second leg, respectively. This facilitates defining four possible states, each of which may be associated with different feature sets, via the controller 16 of FIG. 1.

Thus, embodiments of the present invention have been described herein with reference to a particular embodiment for a particular application. Those having ordinary skill in the art and access to the present teachings will recognize additional modifications, applications, and embodiments within the scope thereof.

It is therefore intended by the appended claims to cover any and all such applications, modifications and embodiments within the scope of the present invention.

Accordingly,

1. A system (14) for configuring a circuit (10) characterized by:
first mechanism (12) for optionally mechanically opening an electrical trace (20) on a printed circuit board (14) to change the state of the trace (20) from closed to open and
second mechanism (16, 18) electrically coupled to the trace (20) for effecting an operational mode of the circuit (10) based on the open or closed state of the trace (20).

2. The system (14) of claim 1 wherein the first mechanism (12) includes mechanism (26, 30) for facilitating physically breaking the electrical trace (20) to effect a permanent mode change for the circuit (10).

3. The system (14) of claim 2 wherein the trace (20) is an inner-layer trace (20).

4. The system (14) of claim 1 wherein the first mechanism (12) includes a tab (26) connecting different sections (22, 24) of the trace (20).

5. The system (14) of claim 4 wherein the tab (26) includes mechanism (28, 30) for facilitating altering the tab (26) to permanently break a connection between the different sections (22, 24) of the trace (20) to transition the circuit (10) from a first operational mode to a second operational mode.

6. The system (14) of claim 5 wherein the mechanism (28, 30) for altering includes mechanism (28) for facilitating application of torque to the tab to permanently break the connection between the different sections (22, 24) of the trace (20).

7. The system (14) of claim 5 wherein circuit (10) communicates with plural tabs (26) and corresponding traces (20) to enable several different operational modes in response to different states indicated via the plural tabs (26).

8. The system (14) of claim 7 wherein the circuit (10) includes a formatter printer circuit assembly (14).

9. The system (14) of claim 8 wherein the circuit (10) further includes a printing subsystem (32) in communication with the formatter printer circuit assembly (14). A system (14) for selectively configuring a circuit (10). The system (14) includes a first mechanism (12) for selectively mechanically opening or closing an electrical trace (20) on a printed circuit board (14). A second mechanism (16) electrically coupled to the trace (20) effects an operational mode of the circuit (10) based on the open or closed state of the trace (20).
